(19) United States
(12) Patent Application Publication
(10) Pub. No.: US 2018/0031748 A1
(43) Pub. Date: Feb. 1, 2018

(54) ANTIREFLECTIVE POLARIZING PLATE AND IMAGE DISPLAY APPARATUS INCLUDING THE SAME

(71) Applicant: DONGWOO FINE-CHEM CO., LTD., Jeollabuk-do (KR)

(72) Inventors: Jung Min CHO, Gangwon-do (KR); Yong Won SEO, Gyeonggi-do (KR); Byoung Chul CHOI, Gyeonggi-do (KR)

(21) Appl. No.: 15/729,009

(22) Filed: Oct. 10, 2017

Related U.S. Application Data
(62) Division of application No. 14/905,030, filed on Jan. 14, 2016.

(30) Foreign Application Priority Data
Jul. 23, 2013 (KR) 10-2013-0086487

(51) Int. Cl. G02B 5/30; G02B 27/28; G02B 1/11; H01L 51/52; G02F 1/13363

(52) U.S. Cl. CPC G02B 5/3041; G02B 27/281; G02B 1/11; G02B 5/3083; G02B 1/14; G02F 2001/133635; G02F 2201/38; H01L 51/5281

(57) ABSTRACT

A polarizing plate includes a polarizer, and a quarter wave film (QWF) layer and a +C (positive C) plate layer, which are disposed on a lower side of the polarizer, wherein a total refractive index ratio Nz of the polarizer, the quarter wave film layer, and the +C plate layer is 0.1 to 0.8, and thereby shows excellent antireflection effects in an oblique direction of a screen as well as in a front direction thereof, and an image display apparatus including the same.

### CROSS-REFERENCE TO RELATED APPLICATION

This application is a divisional application of application Ser. No. 14/905,030, filed on Jan. 14, 2016, which is a National Phase application under 35 U.S.C. §371 of International Application No. PCT/KR2014/004721, filed May 28, 2014, which claims priority to and the benefit of Korean Patent Application No. 10-2013-0086487, filed on Jul. 23, 2013, entire contents of which are incorporated herein by reference.

### BACKGROUND

### 1. Field of the Invention

The present invention relates to an antireflective polarizing plate and an image display apparatus including the same, and more particularly, to a polarizing plate with maximized antireflection effects in an oblique direction of a screen as well as in a front direction thereof and an image display apparatus such as a liquid crystal display (LCD) apparatus, an organic light emitting diode (OLED), or the like, which includes the polarizing plate.

### 2. Description of the Related Art

A polarizing plate is a display related component which generates light vibrating in only one direction. The polarizing plate generally has a structure in which transparent protective films are laminated on both surfaces of a polarizer made of a polyvinyl alcohol (PVA) resin by an adhesive. Herein, the transparent protective film may be replaced by a film having a retardation compensation function depending on its purpose.

The polarizing plate having the above-described structure is widely used in an image display apparatus. For example, in general, two polarizing plates are used for controlling an amount of light emitted from a backlight in a liquid crystal display (LCD) apparatus depending on its purpose, while one polarizing plate is used for controlling a reflectance of light incident onto a panel in an organic light emitting diode (OLED).

One very important issue in image display apparatuses is to improve a contrast thereof, which represents a difference in luminance between the lightest part and the darkest part of a screen. As one method for enhancing the contrast, simply increasing the luminance of a light source may be considered. However, this method has a problem that an amount of power consumed in the backlight of the LCD or organic luminescent materials of the OLED is increased, and thereby a high stress is applied to the device.

In addition, there is also proposed a method of increasing the reflectance by external light by laminating a functional layer such as an anti-reflective film on a surface of the image display apparatus. This method has problems such as a limitation in selection of materials, difficulty in uniform manufacture of a thin film, and the need for additional manufacturing processes or the like.

In order to solve the above-described problems, Korean Patent Laid-Open Publication No. 2003-89500 discloses a polarizing plate which includes a half wave film and a quarter wave film which respectively contain polymerized or vitrified anisotropic materials, and are disposed on a lower side of a polarizer. When the polarizing plate is used in the image display apparatus such as a liquid crystal display (LCD) apparatus, an organic light emitting diode (OLED), or the like, it has a limitation in application due to a still inferior antireflection effect in an oblique direction of a screen, even if it exhibits an excellent antireflection effect in a front direction thereof.

### SUMMARY

Accordingly, it is an object of the present invention to provide a polarizing plate with maximized antireflection effects in an oblique direction of a screen as well as in a front direction thereof and improved reflective color sense.

Another object of the present invention is to provide an image display apparatus such as a liquid crystal display (LCD) apparatus, an organic light emitting diode (OLED), or the like, which includes the polarizing plate with maximized antireflection effects in an oblique direction of a screen as well as in a front direction thereof and improved reflective color sense.

The above objects of the present invention will be achieved by one or more of the following characteristics:

(1) A polarizing plate including: a polarizer; and a quarter wave film (QWF) layer and a +C (positive C) plate layer, which are disposed on a lower side of the polarizer, wherein a total refractive index ratio Nz of the polarizer, the quarter wave film layer, and the +C plate layer is 0.1 to 0.8.

(2) The polarizing plate according to the above (1), wherein the quarter wave film layer has reverse wavelength dispersion characteristics, and the total refractive index ratio is 0.1 to 0.8.

(3) The polarizing plate according to the above (1), wherein the quarter wave film layer has the reverse wavelength dispersion characteristics, and the total refractive index ratio is 0.5 to 0.7.

(4) The polarizing plate according to the above (1), wherein the quarter wave film layer has flat wavelength dispersion characteristics, and the total refractive index ratio is 0.1 to 0.8.

(5) The polarizing plate according to the above (1), wherein the quarter wave film layer has the flat wavelength dispersion characteristics, and the total refractive index ratio is 0.3 to 0.6.

(6) The polarizing plate according to the above (1), wherein the quarter wave film layer has normal wavelength dispersion characteristics, and the total refractive index ratio is 0.4 to 0.8.

(7) The polarizing plate according to the above (1), wherein the quarter wave film layer has the normal wavelength dispersion characteristics, and the total refractive index ratio is 0.5 to 0.7.

(8) The polarizing plate according to the above (1), wherein the +C plate layer has a refractive index ratio Nz of −6 or less.

(9) The polarizing plate according to the above (1), wherein the +C plate layer has a retardation value Rth in a thickness direction of −190 to −10 nm.

(10) The polarizing plate according to the above (1), wherein the quarter wave film layer has the retardation value Rth in the thickness direction of 40 to 180 nm.

(11) The polarizing plate according to the above (1), wherein the quarter wave film layer has a front retardation value Ro of 110 to 180 nm.

(12) The polarizing plate according to the above (1), further including a protective film which is disposed on at least one surface of the polarizer.

(13) The polarizing plate according to the above (1), further including a zero retardation film which is disposed on one surface of the +C plate layer.

(14) An image display apparatus including the polarizing plate according to any one of the above (1) to (13).

(15) The image display apparatus according to the above (14), including an organic light emitting diode (OLED) or liquid crystal display (LCD) apparatus.

The image display apparatus including the polarizing plate of the present invention has a low reflectance in an oblique direction of a screen as well as in a front direction thereof and excellent reflective color sense with no distortion in color sense in the oblique direction.

Further, the polarizing plate of the present invention may provide a condition showing a low reflectance and excellent reflective color sense depending on wavelength dispersion characteristics of the used quarter wave film, and therefore it is possible to achieve the most appropriate configuration depending on intended use and environment.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic view illustrating a relation of refractive indexes nx, ny and nz in x, y and z directions; and

FIGS. 2 to 5 are views schematically illustrating structures of laminates according to embodiments of the present invention, respectively.

### DETAILED DESCRIPTION

The present invention discloses a polarizing plate, which includes a polarizer, and a quarter wave film (QWF) layer and a +C (positive C) plate layer, which are disposed on a lower side of the polarizer, wherein a total refractive index ratio Nz of the polarizer, the quarter wave film layer, and the +C plate layer is 0.1 to 0.8, and thereby shows excellent antireflection effects in an oblique direction of a screen as well as in a front direction thereof, and an image display apparatus including the same.

In the present invention, the refractive index ratio Nz is defined by the following Equation 1.

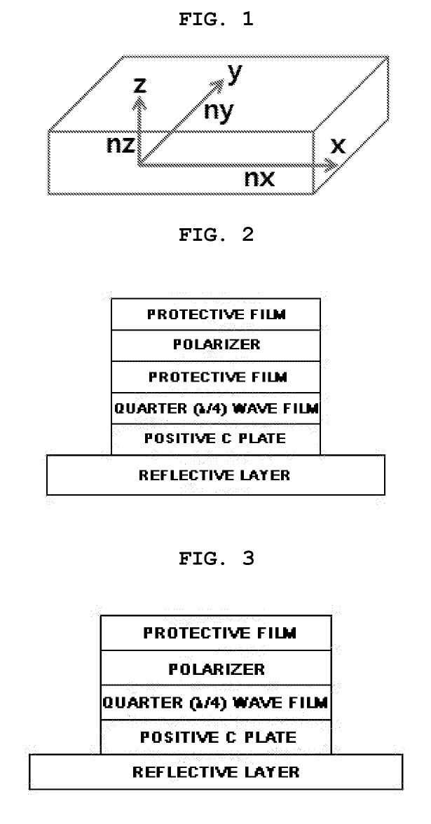

Nz=(nx−nz)/(nx−ny)=Rₜₕ/Rₒ+0.5 [Equation 1]

Wherein nx and ny represent an in-plan refractive index of the film, and in particular, when the vibration direction in which the in-plan refractive index is maximum is set to be the x direction, a refractive index by the light vibrating in this direction is nx, nx and ny are perpendicular to each other and nx≧ny, and nz represents a refractive index in a direction perpendicular to the plane defined by the nx and ny refractive indices (a thickness direction of the film). FIG. 1 schematically illustrates a relation of the refractive indexes nx, ny and nz in x, y and z directions.

In the above Equation 1, Rₜₕ is a retardation value in a thickness direction which represents a difference in the refractive index of the thickness direction with respect to an in-plan average refractive index, and is defined by the following Equation 2. Wherein, Rₒ is a front retardation value which is an actual retardation value obtained when a light passes through a laminate in a normal direction (a vertical direction) of the film, and is defined by the following Equation 3.

Rₜₕ=[(nx+ny)/2−nz]×d [Equation 2]

Wherein nx and ny represent an in-plan refractive index of the film, and in particular, when the vibration direction in which the in-plan refractive index is maximum is set to be the x direction, a refractive index by the light vibrating in this direction is nx, nx and ny are perpendicular to each other and nx≧ny, nz represents a refractive index in a direction perpendicular to the plane defined by the nx and ny refractive indices (a thickness direction of the film), and d represents a thickness of the film.

Rₒ=(nx−ny)×d [Equation 3]

Wherein nx and ny represent an in-plan refractive index of the film, and in particular, when the vibration direction in which the in-plan refractive index is maximum is set to be the x direction, a refractive index by the light vibrating in this direction is nx, nx and ny are perpendicular to each other and nx≧ny, and d represents a thickness of the film.

In addition, conventionally, there are three kinds of retardation plate as follows: 1) A plate in which, when light proceeds in a particular direction, the refractive indexes of all the vibrating directions in the proceeding direction thereof are the same as each other, and therefore an optical axis, which is a proceeding direction of light with no phase difference with respect to the light progressing in the proceeding direction thereof, is present in the in-plane direction; 2) C plate in which the optical axis is present in the vertical direction of the plane; and 3) B plate in which two optical axes are present.

This will be more specifically classified as follows depending on the magnitude relation of refractive index ratio Nz, as well as nx, ny, and nz refractive indices.

(1) Nz=−∞: +C plate (positive C plate), nz>nx=ny

(2) Nz<0: +B plate (positive B plate), nz>nx>ny

(3) Nz=0: −A plate (negative A plate), nx=nz>ny

(4) 0<Nz<1: Z axis alignment film, nx>nz>ny

(5) Nz=1: +A plate (positive A plate), nx>ny=nz

(6) 1<Nz: −B plate (negative B plate), nx>ny>nz

(7) Nz=−: −C plate (negative C plate), nx=ny>nz

However, the above-described definitions are theoretical, and it is substantially difficult to make A, B, and C plates which are perfectly matched with the above-described definitions. Therefore, the A, B, and C plates are conventionally classified by setting values such as the refractive index ratio, the front retardation, or the like to a predetermined range within a scope without departing from the above-described definitions as necessary.

In this regard, the refractive index ratio Nz of −6 or less is also determined to be a +C plate in the present invention.

Hereinafter, the present invention will be described in more detail.

The polarizing plate of the present invention includes a polarizer, and a quarter wave film (QWF) layer and +C (positive C) plate layer, which are disposed on a lower side of the polarizer. In the present invention, the lower side of the polarizer means a side opposite to a visible side. For example, if the polarizing plate of the present invention is arranged on a display panel, the lower side of the polarizer is the display panel side based on the polarizer.

Polarizer

Any conventional polarizer known in the related art may be used without particular limitation thereof. For example, a polarizer which includes a stretched polymer film having a dichroic dye adsorbed and oriented thereon may be used.

Types of the polymer film to form a polarizer are not particularly limited so long as they are possibly dyed by dichroic materials such as iodine and may include, for example, a hydrophilic polymer film such as a polyvinylalcohol film, ethylene-vinyl acetate copolymer film, ethylene-vinyl alcohol copolymer film, cellulose film and/or partially saponified film thereof, or a polyene alignment film such as a dehydrated polyvinylalcohol film, a dehydrochlorinated polyvinyl alcohol film, or the like. Among these, a polyvinylalcohol film is preferable in aspects of excellent effects of reinforcing uniformity of polarities in planes and superior dyeing-affinity to dichroic materials.

More preferably, a polyvinylalcohol film prepared by saponification of a polyvinyl acetate resin may be used. Such a polyvinyl acetate resin may include polyvinyl acetate as a homopolymer of vinyl acetate, as well as a copolymer of vinyl acetate and any other monomer copolymerizable therewith. Such a monomer copolymerizable with vinyl acetate may include, for example, unsaturated carboxylic acid monomers, unsaturated sulfonic acid monomers, olefin monomers, vinyl ether monomers, ammonium group-containing acrylamide monomers, and the like.

In addition, the polyvinyl alcohol resin may include modified resin, for example, aldehyde-modified polyvinylformal, polyvinylacetal, and the like. A saponification value of the polyvinylalcohol resin generally ranges from 85 to 100 mol %, and is preferably 98 mol % or more. Also, a polymerization degree of the polyvinyl alcohol resin generally ranges from 1,000 to 10,000 and preferably 1,500 to 5,000.

The polyvinyl alcohol resin described above may be formed into a film, and the film may be used as a disc film of a polarizer. A method of forming a film using a polyvinyl alcohol resin is not particularly limited, but may use any method known in the related art. Also, a thickness of the disc film is not particularly limited, but may range, for example, from 10 to 150 μm.

The polarizer has the disc film fabricated by any method known in the related art. For example, the disc film of the polarizer may be fabricated by a process of swelling, dyeing, cross-linking, stretching, or the like, and the sequence and number of the processes are not particularly limited. A final overall stretching ratio may range 4.5 to 7.0 times, and preferably 5.0 to 6.5 times of the original size.

As necessary, the polarizing plate according to the present invention may further include a polarizer protective film on at least one surface of the polarizer.

The protective film may include any film having favorable transparency, mechanical strength, thermal stability, moisture shielding properties, isotropic properties, or the like. In particular, the film may be prepared using thermoplastic resin including, for example: polyester resin such as polyethylene terephthalate, polyethylene isophthalate, polyethylene naphthalate, polybutylene terephthalate, etc.; cellulose resin such as diacetyl cellulose, triacetyl cellulose, etc.; polycarbonate resin; acryl resin such as polymethyl (meth)acrylate, polyethyl (meth)acrylate, etc.; styrene resin such as polystyrene, acrylonitrile-styrene copolymer, etc.; polyolefin resin such as polyethylene, polypropylene, cyclic polyolefin or polyolefin having a norbornene structure, ethylene-propylene copolymer, etc.; vinyl chloride resin; polyimide resin such as nylon, aromatic polyimide; imide resin; polyether sulfonic resin; sulfonic resin; polyether ketone resin; polyphenylene sulfide resin; vinylalcohol resin; vinylidene chloride resin; vinylbutyral resin; allylate resin; polyoxymethylene resin; epoxy resin, and the like. Further, a film formed using a blend of at least one thermoplastic resin described above may be used. Furthermore, a film formed using thermosetting resin based on (meth)acrylate, urethane, acrylic urethane, epoxy, silicon, etc. or UV-curable resin may also be used.

The thermoplastic resin of the protective film may be included in an amount of 50 to 100 wt. %, preferably, 50 to 99 wt. %, more preferably, 60 to 98 wt. %, and most preferably, 70 to 97 wt. % to a total weight of the protective film. If a content of the thermoplastic resin is less than 50 wt. %, a high transparency inherently provided to the thermoplastic resin may not be sufficiently expressed.

The transparent protective film described above may include at least one suitable additive. The additive may include, for example, UV-absorbers, antioxidants, lubricants, plasticizers, releasing agents, anti-coloring agents, flame retardants, nucleating agents, antistatic agents, pigments, colorants, and the like.

As necessary, the protective film may be surface treated. Such a surface treatment may include a drying process such as plasma processing, corona treatment, primer processing, etc., or chemical treatment such as alkalization including saponification.

Quarter Wave Film

The quarter wave film layer (λ/4 plate) of the present invention functions to prevent a reflection light.

The quarter wave film layer (λ/4 plate) of the present invention may be obtained, for example, by mono-axially orienting or bi-axially orienting, or by orienting in any other proper way known in the related art.

Types of the polymer compound to form the polymer film are not particularly limited. However, it is preferable that a polymer compound with a high transparency is used for the polymer film so as to be suitably used in the image display apparatus. Such a compound may include a polycarbonate compound, polyester compound, polysulfone compound, polyethersulfone compound, polystyrene compound, polyolefin compound, polyvinyl alcohol compound, cellulose acetate compound, polymethyl methacrylate compound, polyvinyl chloride compound, polyacrylate polyvinyl chloride compound, polyamide polyvinyl chloride compound, etc.

Alternately, the quarter wave film layer (λ/4 plate) may be made of nematic or smectic, and preferably nematic liquid crystal materials which may be polymerized by polymerization in the same reacting system. As a specific example, the quarter wave film layer (λ/4 plate) may be made by coating polymerizable liquid crystal materials on a substrate, orienting the same in plane alignment, and then exposing to heat or UV rays so as to be polymerized.

The quarter wave film layer included in the polarizing plate according to the present invention may have various wavelength dispersion characteristics as necessary. For example, the quarter wave film layer may have reverse wavelength dispersion characteristics, flat wavelength dispersion characteristics, or normal wavelength dispersion characteristics.

When the quarter wave film layer has the reverse wavelength dispersion characteristics, the value of Ro (450 nm)/Ro (550 nm) is 0.7 or more to less than 0.99.

When the quarter wave film layer has the flat wavelength dispersion characteristics, the value of Ro (450 nm)/Ro (550 nm) is 0.99 or more to less than 1.01.

When the quarter wave film layer has the normal wavelength dispersion characteristics, the value of Ro (450 nm)/Ro (550 nm) is 1.01 or more to 2 or less.

The range of total refractive index ratio capable of maximizing the antireflection effects and reflective color sense may be varied depending on the wavelength dispersion characteristics of the quarter wave film layer included in the polarizing plate according to the present invention, which will be described below.

The quarter wave film layer according to the present invention may have various retardation values within a range satisfying the range of 0.1 to 0.8 which is a total refractive index ratio range of the polarizing plate of the present invention. For example, the retardation value Rth in the thickness direction may be 40 to 180 nm, and the front retardation value Ro may be 110 to 180 nm. The polarizing plate may easily satisfy the total refractive index ratio range of the present invention within the above-described range to efficiently express the antireflection effects. However, the above-described range is only an example, and the quarter wave film layer may have another range of retardation values so long as it satisfies the total refractive index ratio range of the polarizing plate of the present invention.

+C Plate Layer

Generally, when the polarizing plate includes only the film layers, reflectance characteristics in an oblique direction (a direction as seen from right and left and top and bottom in the front direction of the visual side of the screen) tend to decrease.

In consideration this, the polarizing plate of the present invention further includes the +C plate layer to improve the reflective color sense in the oblique direction and increase the image quality.

The +C plate layer according to the present invention may be fabricated by orienting the polymer film in any proper way known in the related art, or by applying polymerizable cholesteric liquid crystal compounds to one surface of the substrate, orienting in a predetermined direction, and then curing the same.

When using the polymerizable cholesteric liquid crystal compounds, a zero retardation film may be used as the substrate. In the present invention, the zero retardation film refers to a film in which a substantial phase difference is not generated even if light is transmitted through the film.

Ideally, the +C plate layer according to the present invention has the refractive index ratio Nz with a negative infinity, but it substantially includes the case of having a refractive index ratio Nz of −6 or less. Therefore, the +C plate layer may have various values of retardation value Rth in the thickness direction and the front retardation value Ro within the range satisfying the total refractive index ratio of the polarizing plate of the present invention. For example, the retardation value Rth in the thickness direction may be −190 to −10 nm. If the refractive index ratio of a first retardation layer exceeds −6, or the retardation value Rth in the thickness direction is less than −190 nm or exceeds −10 nm, improvement effect of the reflective color sense may be minimal. In addition, the front retardation value Ro ideally should be 0 nm, but a range which may be substantially considered 0 nm is also included in the present invention. For example, the front retardation value Ro may be −1 to 1 nm. However, the above-described range is only an example, and the quarter wave film layer may have other range of retardation values so long as it satisfies the total refractive index ratio range of the polarizing plate of the present invention.

Polarizing Plate

The polarizing plate of the present invention includes the polarizer, and the quarter wave film layer and the +C plate layer, which are disposed on the lower side of the polarizer, wherein the total refractive index ratio Nz thereof is 0.1 to 0.8. If the total refractive index ratio Nz is less than 0.1 or exceeds 0.8, a difference in reflective color sense is increased and thereby visibility is lowered.

Since the polarizing plate of the present invention includes the polarizer, the quarter wave film layer, and the +C plate layer, the retardation value of each layer may have various values within the range satisfying the above-described total refractive index ratio. Examples of the retardation value of the quarter wave film layer and the +C plate layer are the same as described above. In addition, when the zero retardation film is further used as the protective film of the polarizer or the substrate of the +C plate layer, the retardation values of the polarizer, the quarter wave film layer, and the +C plate layer are properly adjusted so as to satisfy the above-described range of the total refractive index of the polarizing plate in consideration of the retardation value or the refractive index of the protective film or the zero retardation film. Accordingly, the above-described ranges of the retardation value for the respective layers are only a preferable example, and since the total refractive index ratio is obtained from an entire structure on which the respective layers are laminated, the above-illustrated retardation value may be subdivided into a plurality of values for each layer and applied thereto according to particular cases.

For example, when the retardation value in the thickness direction of the quarter wave film layer is 40 nm or more to less than 65 nm, the retardation value in the thickness direction of the +C plate layer may be −130 nm to −10 nm.

In addition, when the retardation value in the thickness direction of the quarter wave film layer is 65 nm or more to less than 80 nm, the retardation value in the thickness direction of the +C plate layer may be −130 nm to −30 nm or less.

Further, when the retardation value in the thickness direction of the quarter wave film layer is 80 nm or more to less than 100 nm, the retardation value in the thickness direction of the +C plate layer may be −180 nm to −50 nm.

Furthermore, when the retardation value in the thickness direction of the quarter wave film layer is 100 nm or more to less than 180 nm, the retardation value in the thickness direction of the +C plate layer may be −180 nm to −80 nm or less.

The polarizing plate of the present invention may have the total refractive index within a more limited range so as to decrease the reflectance and the change in reflective color sense depending on the wavelength dispersion characteristics of the quarter wave film layer.

As one embodiment of the present invention, when the quarter wave film layer has the reverse wavelength dispersion characteristics, the total refractive index ratio may be 0.1 to 0.8, and preferably 0.5 to 0.7. In the above-described range, it is possible to minimize the reflectance and the change in reflective color sense.

As another embodiment of the present invention, when the quarter wave film layer has the flat wavelength dispersion characteristics, the total refractive index ratio may be 0.1 to 0.8, and preferably 0.3 to 0.6. In the above-described range, it is possible to minimize the reflectance and the change in reflective color sense.

As another embodiment of the present invention, when the quarter wave film layer has the normal wavelength dispersion characteristics, the total refractive index ratio may be 0.4 to 0.8, and preferably 0.5 to 0.7. In the above-described range, it is possible to minimize the reflectance and the change in reflective color sense.

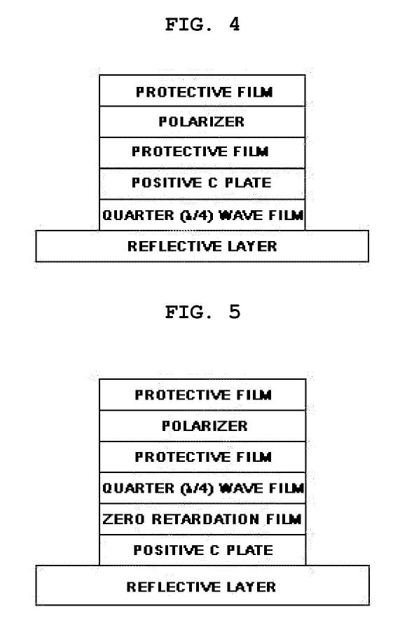

FIGS. 2 to 5 schematically illustrate various embodiments of the polarizing plate according to the present invention, respectively. However, since the drawings attached to the present disclosure are only given for illustrating the preferable embodiments of present invention and function to easily understand the technical spirit of the present invention, it should not be construed as limited to such a description illustrated in the drawings.

As illustrated in FIG. 2, the polarizing plate of the present invention may be provided with a protective film on at least one surface of the polarizer. Conventionally, the polarizer is provided with the protective films on both surfaces thereof, however, as illustrated in FIG. 3, the lower side of the polarizer on which the quarter wave film (QWF) layer and the +C plate layer are disposed may not be provided with the protective film.

The polarizing plate of the present invention includes the quarter wave film (QWF) layer and the +C plate layer disposed on the lower side thereof, however, the laminating order of the quarter wave film (QWF) layer and the +C plate layer is not particularly limited. Therefore, as illustrated in FIGS. 2 and 3, the quarter wave film (QWF) layer and the +C plate layer may be laminated on the lower side of the polarizer in this order, and as illustrated in FIG. 4, the +C plate layer and the quarter wave film (QWF) layer may be laminated on the lower side of the polarizer in this order through the protective film.

FIG. 5 illustrates an embodiment in which the +C plate layer further includes the zero (0) retardation film on one surface thereof. When the +C plate layer is formed by polymerization of the polymerizable liquid crystal compounds, the zero retardation film may be used as the substrate of the polymerizable liquid crystal compounds. Although FIG. 5 illustrates a structure in which the zero retardation film is disposed so as to face the quarter wave film layer, the +C plate layer may be disposed so as to face the quarter wave film layer.

When the polarizing plate of the present invention is configured to include the polarizer, the half wave film disposed on the lower side of the polarizer, and the quarter wave film disposed on the lower side of the half wave film, the polarizer may further include a transparent protective film, an additional retardation plate, a hard coating layer, a touch panel, and the like, which are sequentially disposed on an upper side thereof.

The polarizing plate according to the present invention may be used in the display apparatus, specifically, in: a twisted nematic (TN), high twisted nematic (HTN) or super twisted nematic (STN) mode display; an active matrix driven TN (AMD-TN) display; an in-plane switching (IPS) mode display; or a deformation of aligned phase of nematic (DAP), or vertical alignment (VA) mode display, for example: electrically controlled birefringence (ECB), color super homeotropic (CSH), vertically aligned nematic or cholesteric (VAN or VAC) displays; multi-domain vertical alignment (MVA) mode displays; or bent alignment mode or hybrid alignment mode displays, for example: optically compensated bend (OCB) cell or optically compensated birefringence (OCB), reflective OCB (R-OCB), hybrid aligned nematic (HAN) or Pi-cell display; or organic light emitting diode (OLED).

In particular, the polarizing plate according to the present invention may be preferably used in the organic light emitting diode (OLED), or reflective type or transmissive type LCD to improve optical and antireflection characteristics. As an example of use, the polarizing plate according to the present invention may be disposed on the upper side of a cathode (a reflective layer) of the organic light emitting diode (OLED) to decrease the reflectance of light incident onto the panel in the front and oblique directions, while maintaining excellent reflective color sense in the oblique direction.

Other conventional configurations used in the field of the image display apparatus such as the organic light emitting diode (OLED), liquid crystal display (LCD), or the like may be employed in the present invention, except that the conventional polarizing plate is replaced by the polarizing plate according to the present invention.

Hereinafter, preferred embodiments are proposed to more concretely describe the present invention. However, the following examples are only given for illustrating the present invention and those skilled in the art will obviously understand that various alterations and modifications are possible within the scope and spirit of the present invention. Such alterations and modifications are duly included in the appended claims.

### EXAMPLE

### Examples 1 to 19 and Comparative Examples 1 to 10

A polarizing plate having the structure of FIG. 2 was adhered onto a cathode of an OLED. TAC protective films (both of Ro and Rth are zero) are disposed on both surfaces of a PVA polarizer, and a quarter wave film layer and a +C plate layer are disposed on the TAC protective film disposed on a lower side of the polarizer to prepare polarizing plates having the configurations described in Table 1 below. However, as the protective film of the polarizer, TAC films were used in the case of ensuring normal wavelength dispersion characteristics of the quarter wave film layer, polycarbonate (PC) films were used in the case of ensuring reverse wavelength dispersion characteristics, and COP films were used in the case of ensuring flat wavelength dispersion characteristics, respectively.

In case of Examples 17 to 19, zero retardation films (both of Ro and Rth are zero) were further disposed between the quarter wave film layer and the +C plate layer.

Chromaticity coordinates in which a* and b* chromaticity diagrams are applied to the prepared polarizing plates were obtained, and ΔE* values (range of color senses) were calculated therefrom. ΔE* values were calculated by using ΔE*=V((Δa*)²+(Δb*)²), and results thereof are shown in Table 1 below.

TABLE 1

| | λ/4 Film layer | | | | | | | | |
|---|---|---|---|---|---|---|---|---|---|
| | | Ro | | | | | | | |
| | Wavelength | (450 nm)/ | | | +C Plate | | | | |
| | dispersion | Ro | Rₒ | Rₜₕ | | Rₒ | Rₜₕ | Total | |
| Section | characteristic | (550 nm) | (nm) | (nm) | Used | (nm) | (nm) | Nz | ΔE* |
| Example 1 | Reverse | 0.75 | 145 | 120 | Yes | 0 | −100 | 0.6 | 8 |
| Example 2 | Reverse | 0.8 | 145 | 120 | Yes | 0 | −90 | 0.7 | 9 |
| Example 3 | Reverse | 0.82 | 145 | 120 | Yes | 0 | −120 | 0.5 | 11 |
| Example 4 | Reverse | 0.85 | 145 | 120 | Yes | 0 | −80 | 0.8 | 14 |
| Example 5 | Reverse | 0.9 | 145 | 120 | Yes | 0 | −140 | 0.3 | 16 |
| Example 6 | Reverse | 0.95 | 145 | 120 | Yes | 0 | −180 | 0.1 | 21 |
| Example 7 | Flat | 0.99 | 140 | 70 | Yes | 0 | −70 | 0.5 | 9 |
| Example 8 | Flat | 0.99 | 140 | 70 | Yes | 0 | −60 | 0.6 | 12 |
| Example 9 | Flat | 0.99 | 140 | 70 | Yes | 0 | −100 | 0.3 | 13 |
| Example 10 | Flat | 1.0 | 140 | 70 | Yes | 0 | −130 | 0.1 | 16 |
| Example 11 | Flat | 1.0 | 140 | 70 | Yes | 0 | −30 | 0.8 | 20 |
| Example 12 | Normal | 1.2 | 145 | 70 | Yes | 0 | −60 | 0.6 | 8 |
| Example 13 | Normal | 1.3 | 145 | 70 | Yes | 0 | −40 | 0.7 | 10 |
| Example 14 | Normal | 1.5 | 145 | 70 | Yes | 0 | −70 | 0.5 | 12 |
| Example 15 | Normal | 1.8 | 145 | 70 | Yes | 0 | −30 | 0.8 | 15 |
| Example 16 | Normal | 1.9 | 145 | 70 | Yes | 0 | −90 | 0.4 | 18 |
| Example 17 | Reverse | 0.75 | 145 | 120 | Yes | 0 | −100 | 0.6 | 8 |
| Example 18 | Flat | 0.99 | 140 | 70 | Yes | 0 | −70 | 0.5 | 9 |
| Example 19 | Normal | 1.02 | 145 | 70 | Yes | 0 | −60 | 0.6 | 8 |
| Comparative | Reverse | 0.75 | 145 | 120 | Yes | 0 | 0 | 1.3 | 25 |
| Example 1 | | | | | | | | | |
| Comparative | Reverse | 0.8 | 145 | 120 | Yes | 0 | −60 | 0.9 | 23 |
| Example 2 | | | | | | | | | |
| Comparative | Reverse | 0.82 | 145 | 120 | Yes | 0 | −195 | 0.05 | 25 |
| Example 3 | | | | | | | | | |
| Comparative | Reverse | 0.85 | 145 | 120 | No | — | — | 1 | 25 |
| Example 4 | | | | | | | | | |
| Comparative | Flat | 0.99 | 140 | 70 | Yes | 0 | −10 | 0.9 | 25 |
| Example 5 | | | | | | | | | |
| Comparative | Flat | 0.99 | 140 | 70 | Yes | 0 | −140 | 0.05 | 24 |
| Example 6 | | | | | | | | | |
| Comparative | Flat | 1.0 | 140 | 70 | No | — | — | 1 | 24 |
| Example 7 | | | | | | | | | |
| Comparative | Normal | 1.2 | 145 | 70 | Yes | 0 | −10 | 0.9 | 25 |
| Example 8 | | | | | | | | | |
| Comparative | Normal | 1.3 | 145 | 70 | Yes | 0 | −140 | 0.05 | 40 |
| Example 9 | | | | | | | | | |
| Comparative | Normal | 1.5 | 145 | 70 | No | — | — | 1 | 31 |
| Example 10 | | | | | | | | | |

According to Table 1, it can be seen that the polarizing plate of the present invention had ΔE* of 21 or less, and thereby exhibited a small change in reflective color sense, while for the case of the comparative examples having a refractive index ratio out of the present invention.

What is claimed is:

1. A polarizing plate comprising:
a polarizer; and
a laminate including a quarter wave film (QWF) layer and a +C (positive C) plate layer, which is disposed on a lower surface of the polarizer, the quarter wave film having reverse wavelength dispersion characteristics,
wherein a refractive index ratio (Nz) defined by Equation 1 below of the laminate is 0.1 to 0.8, a retardation value in a thickness direction (Rth) defined by Equation 2 below of the laminate is −60 to 40 nm, a front retardation value (Ro) defined by Equation 3 below of the laminate is 110 to 180 nm, and a wavelength dispersion value of the quarter wave film defined by Equation 4 below is 0.7 to 1:
Nz=(nx−nz)/(nx−ny)=Rₜₕ/Rₒ+0.5 [Equation 1]
Rₜₕ=[(nx+ny)/2−nz]×d [Equation 2]
Rₒ=(nx−ny)×d [Equation 3]
Dispersion value=Ro (at 450 nm)/Ro (at 550 nm) [Equation 4].

2. The polarizing plate of claim 1, wherein the quarter wave film layer is interposed between the polarizer and the +C plate layer.

3. The polarizing plate of claim 1, further comprising a zero-retardation film on at least one surface of the +C plate layer.

4. The polarizing plate of claim 3, wherein the zero-retardation film is interposed between the quarter wave film layer and the +C plate layer.

5. The polarizing plate of claim 1, further comprising a protective film on at least one surface of the polarizer.

6. The polarizing plate of claim 5, wherein the protective film includes an upper protective film formed on an upper surface of the polarizer, and a lower protective film formed on the lower surface of the polarizer.

7. The polarizing plate of claim 6, wherein the quarter wave film layer is in contact with the lower protective film.

8. The polarizing plate of claim 1, wherein an upper surface of the polarizer is toward a visible side, and the +C plate layer is configured to be disposed on a reflective layer of an organic light emitting diode (OLED) device.

9. An organic light emitting diode (OLED) device, comprising:
an OLED panel including a reflective layer; and
the polarizing plate of claim 1 on the reflective layer.

10. The OLED device of claim 9, wherein the +C plate layer of the polarizing plate is disposed on the reflective layer, and the polarizer is toward a visible side.

11. The OLED device of claim 10, wherein the reflective layer includes a cathode.
